(19) United States
(12) Patent Application Publication
(10) Pub. No.: US 2014/0077843 A1
(43) Pub. Date: Mar. 20, 2014

(54) Pipelined Bus-Splitting Digital Delta-Sigma Modulator for Fractional-N Frequency Synthesizer System and Method

(71) Applicants: Michael Peter Kennedy, Co. Cork (IE); Brian Patrick Fitzgibbon, Co. Cork (IE)

(72) Inventors: Michael Peter Kennedy, Co. Cork (IE); Brian Patrick Fitzgibbon, Co. Cork (IE)

(21) Appl. No.: 13/906,978

(22) Filed: May 31, 2013

Related U.S. Application Data
(60) Provisional application No. 61/653,754, filed on May 31, 2012.

(51) Int. Cl. H03M 3/00

(52) U.S. Cl. CPC H03M 3/39
USPC 327/105; 341/143

(57) ABSTRACT

The invention provides a digital modulator system for use in a fractional-N frequency synthesizer, said system comprising: a first pipelined modulator configured to receive a digital signal via a bus signal; a second pipelined modulator configured to receive a part of said digital signal; and said system is adapted to split the bus signal by passing least significant bits (LSBs) of said digital signal through the second modulator, combining the output of said second modulator with the most significant bits (MSBs) of said digital signal, and adapted to pass the combined signal through said first pipelined modulator. The combination of bus-splitting and pipelining in the modulator system is configured to provide an output signal to maximize the update rate of a multi-modulus divider of said fractional-N frequency synthesizer.

### FIELD OF THE DISCLOSURE

The disclosure relates to a Digital Delta-Sigma Modulator for use in a Fractional-N Frequency Synthesizer system and method.

### BACKGROUND

A frequency synthesizer is an essential component of wireless communication systems. An indirect frequency synthesizer based on a phase-locked loop produces an output frequency that is locked to a precise reference. In this application, the output frequency will be referred to as the VCO frequency, denoted f_{VCO}. The reference frequency, corresponding to that at the reference input of the phase detector, is denoted f_{PD}.

In an integer-N frequency synthesizer, the relationship between the output and reference frequencies is:

f_{VCO}=N₀f_{PD},

where the division ratio N₀ is a positive integer. The frequency resolution is given by fᵣₑₛ=f_{PD}.

An error signal is produced by the phase detector with a period of 1/f_{PD}. This produces a so-called reference spur. To attenuate the reference spur, the bandwidth of the loop filter is made much less than f_{PD}. This low bandwidth has two important consequences:

1) the transient response of the loop is relatively slow, and
2) the energy storage elements in the loop filter are physically large.

An improved solution is the so-called fractional-N frequency synthesizer, in which the average division ratio in the feedback path is a fractional number. For the same frequency resolution fᵣₑₛ, a larger value of f_{PD}, and consequently a larger loop bandwidth, can be used. This has the advantages of a faster transient response and a physically smaller loop filter.

An integer-N synthesizer has a fixed division ratio N₀ in the feedback path between the VCO and the phase detector. By contrast, in a fractional-N frequency synthesizer as disclosed by T. Riley, “Frequency synthesizers having dividing ratio controlled by sigma-delta modulator,” U.S. Pat. No. 4,965,531, Oct. 23, 1990, shown in FIG. 1, the value of the division ratio of the multimodulus divider (MMD) is updated at a rate fₛ. The instantaneous value of the division ratio is determined by a divider controller. A typical implementation of a divider controller, such as that shown in FIG. 2, comprises a Digital Delta-Sigma Modulator (DDSM) with input N₁, modulus M₁, and output Y₁ and a summing element, as disclosed in B. Miller, “Multiple-modulator fractional-n divider,” U.S. Pat. No. 5,038,117, Aug. 6, 1991. N₁, and M₁, are chosen such that the average value of Y₁ is N₁/M₁. The relationship between the output and reference frequencies in the fractional-N frequency synthesizer is then:

$${f}_{VCO} = ( {N}_{0} + \frac{{N}_{1}}{{M}_{1}} ) {f}_{PD} ,$$

where M₁ is called the modulus of the DDSM. For ease of implementation, M₁ is typically a large power of two, N₀ and N₁ are positive integers, and N_{1<M}₁.

The frequency resolution is defined by:

$${f}_{res} = \frac{1}{M 1} {f}_{PD}$$

in this case. For the same value of f_{PD}, the frequency resolution of the fractional N synthesizer is improved by a factor of M₁ compared to the integer-N architecture.

Advanced frequency synthesizers need f_{PD} to be large for fast switching and low phase noise. Furthermore, they require a small frequency step for high resolution. In any given technology, there is a maximum frequency at which the MMD can be updated; the larger the modulus, the smaller this frequency is. Hence a problem with fractional synthesizers is that the implementation technology imposes an upper bound on the update frequency f_{PD} and therefore the modulus and the resolution.

It is therefore an object of the disclosure to provide a new modulator design for increasing the frequency at which the MMD can be updated and thereby improving the performance of a fractional synthesizer system and method.

### SUMMARY OF THE DISCLOSURE

Accordingly there is provided a digital modulator system for use in a fractional-N frequency synthesizer, said system comprising:
a first pipelined modulator configured to receive a digital signal via a bus signal;
a second pipelined modulator configured to receive a part of said digital signal; and
said system is adapted to split the bus signal by passing least significant bits (LSBs) of said digital signal through the second modulator, combining the output of said second modulator with the pipelined most significant bits (MSBs) of said digital signal, and adapted to pass the combined signal through said first pipelined modulator.

In one embodiment said first or second modulator comprises a digital delta-sigma modulator.

In one embodiment said first modulator comprises pipelined logic, such that said pipelining of the modulators, the digital signal, and the combination logic allows higher operation speed of said digital modulator system.

In one embodiment the system comprises nested pipelining adapted to split the bus signal more than two times.

In one embodiment the combination of bus-splitting and pipelining in the modulator system is configured to provide an output signal to maximize the update rate of a multimodulus divider of said fractional-N frequency synthesizer. It will be appreciated that fractional-N frequency synthesizer with higher f_{PD} facilitated by pipelined bus-splitting DDSM. It will be further appreciated that a fractional-N frequency synthesizer with higher f_{PD} is facilitated by pipelined bus-splitting DDSM.

In another embodiment the invention provides a new fractional-N frequency synthesizer which uses a combination of bus-splitting and pipelining to allow the controller of the multi-modulus divider to operate at a higher update rate and/or with a larger word length than would otherwise be possible. This offers at least two advantages over state of the art solutions, namely: (a) a higher update rate enables the use of a higher reference frequency, resulting in a smaller loop filter, a smaller division ratio, and therefore lower phase noise; (b) a larger word length enables the use of a larger modulus, resulting in higher frequency resolution.

In one embodiment there is provided a digital modulator system for use in a fractional-N frequency synthesizer, said system comprising:
a first pipelined modulator configured to receive a digital signal delivered via a bus signal;
a second pipelined modulator configured to receive a part of said digital signal; and
said system is adapted to split the bus signal by passing at least part of said digital signal through the second modulator, combining the output of said second modulator with the pipelined at least part of said digital signal, and adapted to pass the combined signal through said first pipelined modulator.

In another embodiment there is provided is provided a digital modulator system for use in a fractional-N frequency synthesizer, said system comprising:
first pipelined modulator configured to receive a digital signal delivered via a bus signal;
a second pipelined modulator configured to receive a part of said digital signal; and said system is adapted to split the bus signal into a first and second part and configured to pass a first part of said signal through the second modulator and passing the second signal through the first modulator in a pipelined arrangement.

In a further embodiment A fractional-N frequency synthesizer comprising a digital modulator system, said system comprising:
a first pipelined modulator configured to receive a digital signal delivered via a bus signal;
a second pipelined modulator configured to receive a part of said digital signal; and
said system is adapted to split the bus signal by passing least significant bits (LSBs) of said digital signal through the second modulator, combining the output of said second modulator with the pipelined most significant bits (MSBs) of said digital signal, and adapted to pass the combined signal through said first pipelined modulator.

In another embodiment there is provided a fractional-N frequency synthesizer comprising a digital modulator system, wherein the system comprises a first and a second modulator configured with a bus-splitting function and a pipelining function to allow the controller of a multi-modulus divider to operate.

There is also provided a computer program comprising program instructions for causing a computer program to carry out the above method which may be embodied on a record medium, carrier signal or read-only memory.

### BRIEF DESCRIPTION OF THE DRAWINGS

The invention will be more clearly understood from the following description of an embodiment thereof, given by way of example only, with reference to the accompanying drawings, in which:—

FIG. 1 illustrates a block diagram of a fractional-N frequency synthesizer;

FIG. 2 illustrates a divider controller in a fractional-N frequency synthesizer;

FIG. 3 illustrates a block diagram of a conventional third-order DDSM;

FIG. 4a, b, and c illustrate implementations of the DDSM1, DDSM2, and DDSM3 configurations;

FIG. 5 illustrates a power spectrum of the output of the modulator shown FIG. 3;

FIG. 6 illustrates a block diagram of a nested bus-splitting DDSM3;

FIG. 7 illustrates the power spectrum of the output of the nested bus-splitting 1-2-3 DDSM3 in FIG. 6;

FIG. 8a, b, and c illustrate prior art block diagrams of pipelined first-, second-, and third-order MASH DDSMs, labeled pDDSM1, pDDSM2, and pDDSM3, respectively;

FIG. 9 illustrates a block diagram of a pipelined nested bus-splitting modulator system, according to one embodiment of the invention; and

FIGS. 10 and 11 show output spectra of a conventional pipelined DDSM3 with a bus width N=25 bits and a 9-8-8-bit pipelined nested bus-splitting 1-2-3 DDSM3.

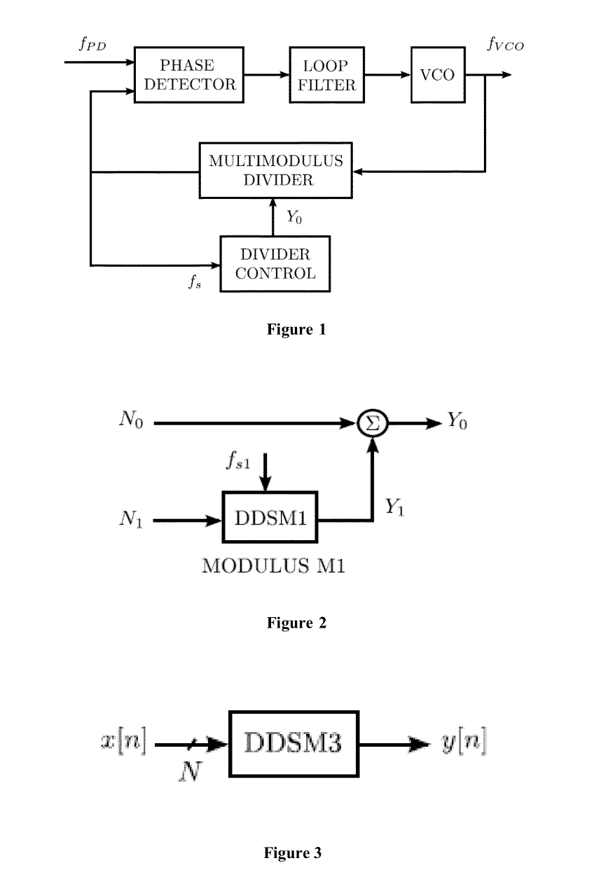

### DETAILED DESCRIPTION OF THE DRAWINGS

A fractional-N frequency synthesizer generates a frequency f_{VCO} which is a rational multiple of a precise reference frequency (f_{PD}). The smallest frequency step (fᵣₑₛ=f_{PD}/M₁) is determined by the modulus (M₁) of the digital delta-sigma modulator (DDSM) which controls the divider in the feedback path of a phase-locked loop: the larger the modulus, the smaller the frequency step.

The DDSM must perform a number of computations per clock cycle. The speed at which the DDSM can be clocked (denoted f_{DDSM}) is determined by the time taken to complete the slowest step in the computation, typically the addition of two binary words. In a typical DDSM, the modulus M₁ is related to the bus width N by:

M₁=2^{N}

The time taken to complete the addition of two N-bit words can be made to scale almost linearly with N. Thus, the maximum frequency at which the DDSM can be clocked is determined by the inherent speed of the technology (fₘₐₓ) and the bus width N.

$${f}_{DDSM} ∝ \frac{{f}_{max}}{N} .$$

All of the computation in the DDSM in a frequency synthesizer that is required to calculate the next update of the multi-modulus divider must be completed within one cycle of the DDSM's clock. The maximum clock frequency of the DDSM is f_{PD}. Thus,

$${f}_{PD} \leq {f}_{DDSM} ∝ \frac{{f}_{max}}{N} .$$

Advanced frequency synthesizers need f_{PD} to be large for fast switching and low phase noise; they also require a small frequency step (equivalently, large N) for high resolution. Note, however, that the upper bound on f_{PD} scales as 1/N.

The modulator of the present invention relaxes the dependence of f_{DDSM} on the modulus M₁, permitting a higher value of f_{PD} and/or a higher value of modulus (and consequently a smaller fᵣₑₛ) in a given technology than the state of the art solution. By replacing a conventional DDSM with the pipelined bus-splitting DDSM herein described, this invention can improve the performance of every existing fractional-N frequency synthesizer.

FIG. 3 shows a block diagram of a conventional third-order DDSM, henceforth denoted DDSM3. The input x[n] is an N-bit word. The z-transform of the output Y (z) is defined by:

Y(z)=STF(z)X(z)+NTF(z)Eq₃(z) (1)

where X(z), Eq₃ (z), STF(z) and NTF(z) are the z-transforms of the input signal, the quantization noise and the signal and noise transfer functions, as shown in a publication by K. Hosseini and M. Kennedy, Minimizing Spurious Tones in Digital Delta-Sigma Modulators, Springer, 2011.

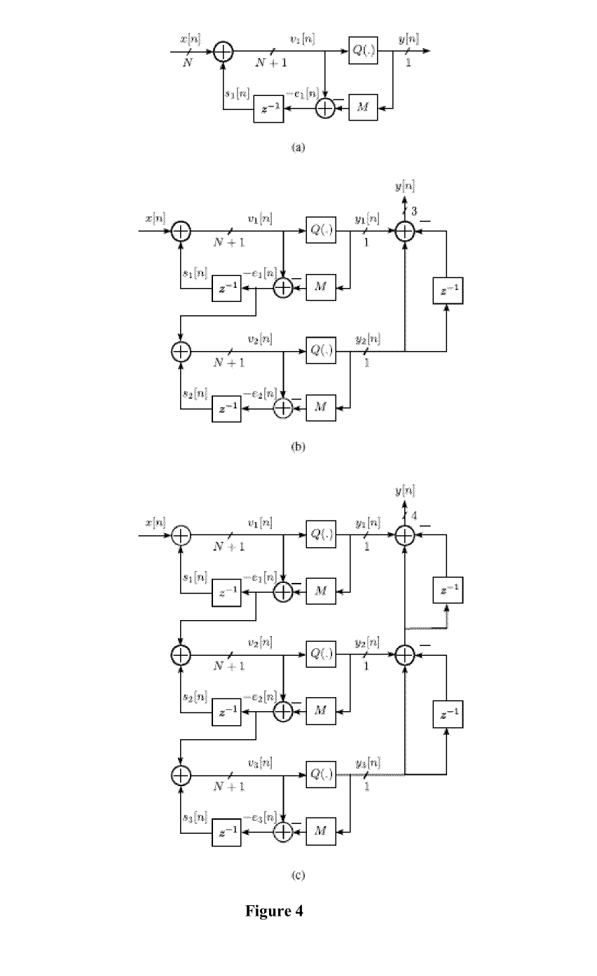

A popular implementation of the DDSM3 configuration is the Multi stage noise Shaping (MASH) architecture shown in FIG. 4. In this case, the output Y (z) is given by

$$Y ( z ) = \frac{1}{M} X ( z ) + {( 1 - {z}^{- 1} )}^{3} {E}_{q 3} ( z ) .$$

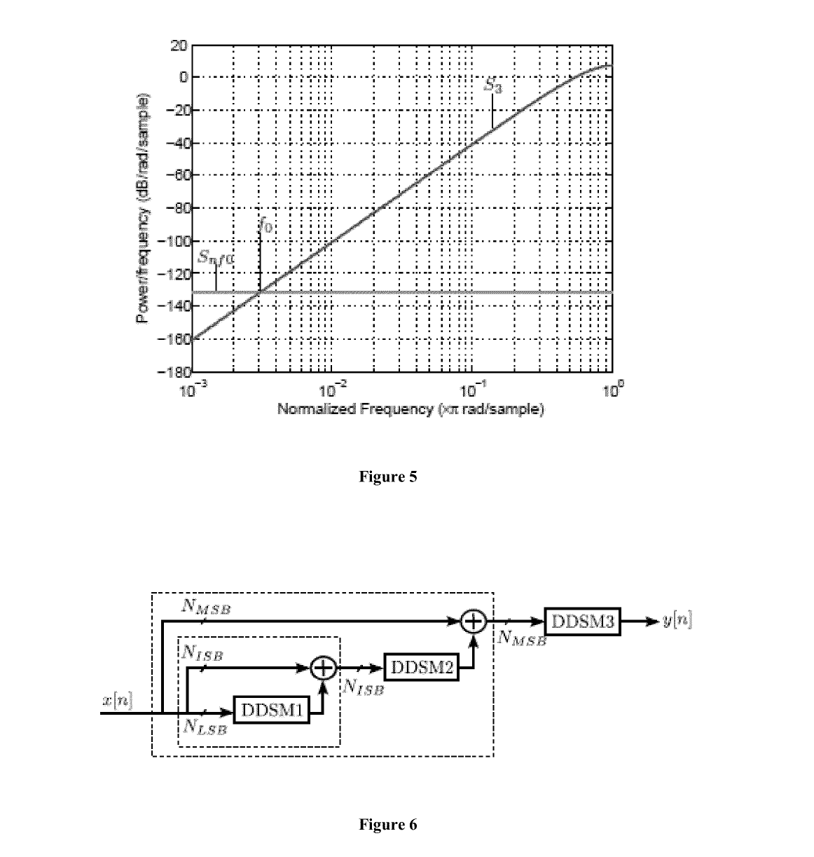

The power spectrum of the output, shown in FIG. 5, comprises two terms, S_{nf0} associated with the N-bit input signal x[n] signal and S₃ defined by the shaped quantization noise.

The idea of bus-splitting as described in a paper by B. Fitzgibbon, M. Kennedy, and F. Maloberti, “Hardware reduction in digital delta-sigma modulators via bus-splitting and error masking—Part I: Constant input,” IEEE Trans. Circuits and Systems—Part I: Regular Papers, vol. 58, no. 9, pp. 2137-2148, September 2011 (and further developed in B. Fitzgibbon, M. P. Kennedy and F. Maloberti. Hardware Reduction in Digital Delta-Sigma Modulators via Bus-Splitting and Error Masking—Part II: Non-constant Input. IEEE Trans. Circuits and Systems-Part I, vol. 59, no. 9, pp. 1980-1991, September 2012) shows that the shaped quantization noise produced by lower order auxiliary DDSMs that preprocess the LSBs of a digital signal before applying in to a main DDSM can be masked by the shaped quantization noise of the latter. The inventors found that instead of passing a signal directly through a (primary) DDSM with a wide bus, the signal x is pre-processed by first passing its least significant bits (LSBs) through a secondary DDSM, thereby reducing the word length of the signal applied to the primary DDSM. If the shaped quantization noise added by the secondary DDSM is spectrally masked by the shaped quantization noise added by the primary DDSM, then the overall system performance is not degraded. However, the bus width of the primary DDSM is reduced, thereby allowing it to be clocked at a higher speed. In the frequency synthesizer application, this enables a higher update rate for the multi-modulus divider.

It will be appreciated that the bus can be split more than once. When the bus is split multiple times, this is called nested bus-splitting. FIG. 6 shows a block diagram of a nested bus-splitting DDSM3, where the N-bit bus has been split into N_{MSB} most significant bits, N_{ISB} intermediate significant bits, and N_{LSB} least significant bits. The primary, secondary, and tertiary DDSMs are labelled DDSM3, DDSM2, and DDSM1, respectively.

The output Y (z) in this case is defined by:

$$Y ( z ) = \frac{X ( z )}{M} + NTF ( z ) {E}_{q 3} ( z ) + {NTF}_{1} ( z ) {E}_{q 1} ( z ) + {NTF}_{2} ( z ) {E}_{q 2} ( z ) , \qquad ( 3 )$$

where STF(z) and NTF(z) are the same z-transforms of the signal and noise transfer functions as before, and NTF₁ (z) and NTF₂ (z) are the noise transfer functions of the DDSM1 and DDSM2, respectively.

In the case where DDSM1, DDSM2, and DDSM3 are of the form shown in FIGS. 4,a, b and c, respectively, the output Y (z) is given by:

$$Y ( z ) = STF ( z ) X ( z ) + {( 1 - {z}^{- 1} )}^{3} {E}_{q 3} ( z ) + \frac{( 1 - {z}^{- 1} )}{{2}^{{N}_{ISB} + {N}_{MSB}}} {E}_{q 1} ( z ) + \frac{{( 1 - {z}^{- 1} )}^{2}}{{2}^{{N}_{MSB}}} {E}_{q 2} ( z ) . \qquad ( 4 )$$

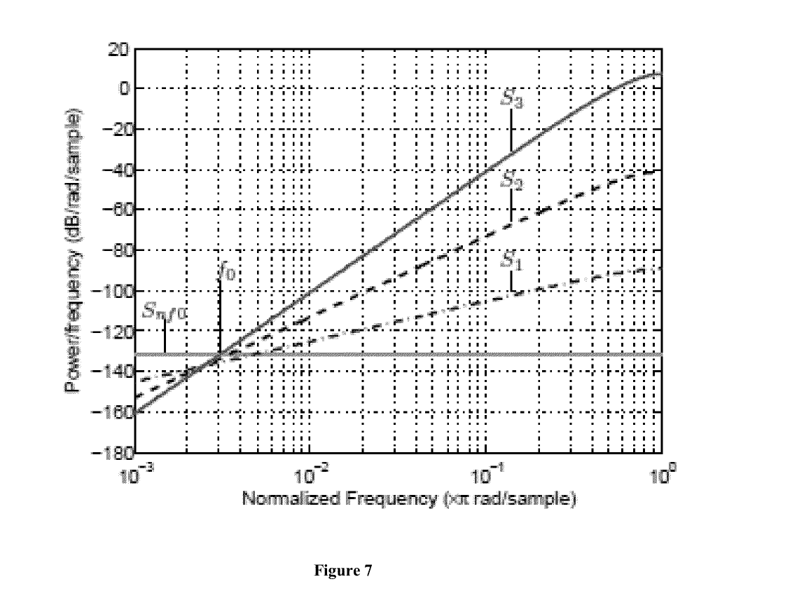

The power spectrum of the output, shown in FIG. 7, comprises four terms: S_{nf0} and S₃ as before, plus two additional terms S₂ and S₁ due to the secondary and tertiary DDSMs, respectively. With appropriate choices of N_{MSB}, N_{ISB}, and N_{LSB}, the additional quantization noise components due to bus splitting can be masked by S₃. In this case, the spectral performance is unchanged but the widest bus is now max(N_{MSB}, N_{ISB}, N_{LSB}), which can be considerably less than N.

The system provides a pipelined bus-splitting DDSM. Although bus-splitting alone reduces the bus width and thereby facilitates an increased update rate of the DDSM, the combination of employing pipelining allows even higher operation speeds. The output Y(z) of a typical pipelined 1^{th} order DDSM is defined by:

$$Y ( z ) = {z}^{- l} \frac{X ( z )}{M} + {( 1 - {z}^{- 1} )}^{l} {E}_{q l } ( z ) .$$

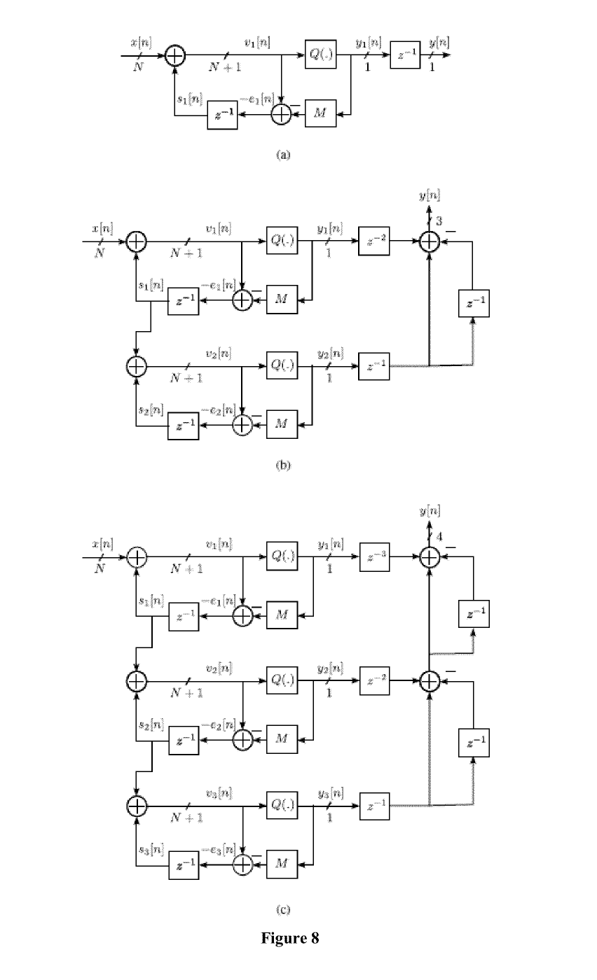

FIG. 8 shows block diagrams of pipelined first-, second- and third-order MASH DDSMs, denoted pDDSM1, pDDSM2, and pDDSM3, respectively.

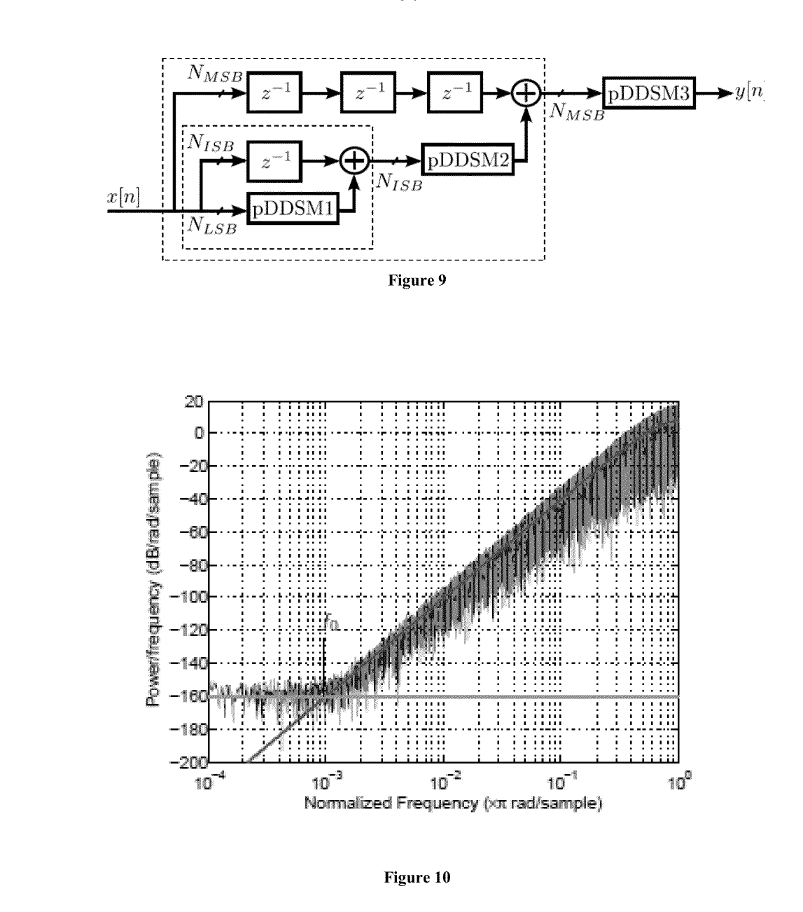

In order to maximize the rate at which the output Y of the DDSM is updated in the frequency synthesizer application, the bus-splitting DDSM is pipelined, as shown in FIG. 9. In this figure, pDDSM1, pDDSM2, and pDDSM3 are pipelined first-, second- and third-order MASH DDSMs. The throughput is determined by the slowest digital block in the chain, namely the adder with the widest bus.

### Example Embodiment

The design example, as shown in FIG. 9, provides for a zeroth-order dithered 25-bit MASH DDSM3. Using the design methodology of the invention, the appropriate word lengths for the pipelined nested bus-splitting 1-2-3 DDSM3 are NMSB=9, NISB=8, and NLSB=8. The input value is set to 3355443 to produce a fractional division ratio of approximately 0.1.

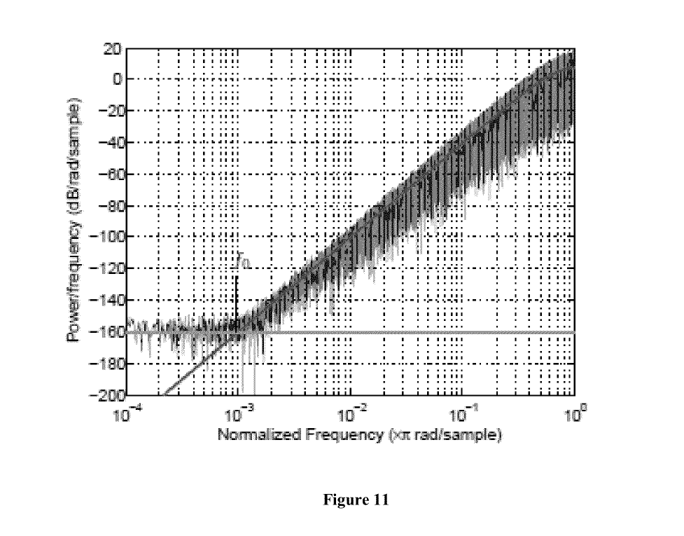

FIGS. 10 and 11 show output spectra of a conventional pipelined DDSM3 with a bus width N=25 bits and a 9-8-8-bit pipelined nested bus-splitting 1-2-3 DDSM3. The spectra are almost identical but the bus width of the DDSM3 in the conventional case is 25 bits, while that in the pipelined nested bus-splitting case is just 9 bits. The speed bottleneck is a 25-bit adder in the first case and a 9-bit adder in the second. When used in a frequency synthesizer, the update rate of the MMD with a conventional DDSM3 is determined by the time taken to add two 25-bit words. By contrast, the update rate in the synthesizer with a pipelined nested-bus-splitting DDSM3 is determined by the time taken to add two 9-bit words. Thus, the pipelined nested bus-splitting DDSM has a considerable advantage over all other existing systems in terms of speed.

The speed bottleneck in a fractional-N frequency synthesizer is frequently the time required by the DDSM in the divider controller to calculate and update the division ratio. The update rate is inversely proportional to the bus width of the modulator. The throughput of a DDSM can be maximized by exploiting a combination of bus-splitting and pipelining. Bus-splitting reduces the bus width, thereby enabling a higher update rate. Pipelining maximizes the throughput, albeit increasing the latency. In frequency synthesis applications, latency is less important than update rate.

By increasing the update rate, a larger reference frequency f_{PD} can be used. This has advantages in terms of the size of the loop filter and the noise performance of the system. If a higher reference frequency is not required, the extra speed can be used to increase the effective bus width of the DDSM, thereby increasing the frequency resolution.

The embodiment described herein comprises an integrated circuit. Although it will be appreciated that the system can be applied to all DDSM architectures including EFM and SQ-DDSM, the greatest speed advantage found to date is in MASH architectures. All orders of modulator (not just third order) can be used to implement the invention.

It will be further appreciated to the skilled person in the art that all variants of bus-splitting (not just 1-2-3, e.g. 1-3, 2-3), variants of clocking schemes (e.g. DDMs clocked at different rates), variants of pipelining (not just every stage), variants of adder (not just ripple carry), variants of DDSM (not just power of 2 modulus) as well as modifications to increase the spur performance of the modulator, including dither, setting initial conditions, and architectural modification, can be used in order to bring the invention into effect.

The embodiments in the invention described with reference to the drawings comprise a computer apparatus and/or processes performed in a computer apparatus. However, the invention also extends to computer programs, particularly computer programs stored on or in a carrier adapted to bring the invention into practice. The program may be in the form of source code, object code, or a code intermediate source and object code, such as in partially compiled form or in any other form suitable for use in the implementation of the method according to the invention. The carrier may comprise a storage medium such as ROM, e.g. CD ROM, or magnetic recording medium, e.g. a memory stick or hard disk. The carrier may be an electrical or optical signal which may be transmitted via an electrical or an optical cable or by radio or other means.

In the specification the terms “comprise, comprises, comprised and comprising” or any variation thereof and the terms include, includes, included and including” or any variation thereof are considered to be totally interchangeable and they should all be afforded the widest possible interpretation and vice versa.

The invention is not limited to the embodiments hereinbefore described but may be varied in both construction and detail.

1. A digital modulator system comprising:
a first pipelined modulator configured to receive a digital signal delivered via a bus signal;
a second pipelined modulator configured to receive a part of said digital signal; and
said system is adapted to split the bus signal by passing least significant bits (LSBs) of said digital signal through the second modulator, combining the output of said second modulator with the pipelined most significant bits (MSBs) of said digital signal, and adapted to pass the combined signal through said first pipelined modulator.

2. The digital modulator system as claimed in claim 1 wherein said first modulator comprises a digital delta-sigma modulator.

3. The digital modulator system as claimed in claim 1 wherein said second modulator comprises a digital delta-sigma modulator.

4. The digital modulator system as claimed in claim 1 wherein said first modulator comprises pipelined logic, such that said pipelining of the modulators, the digital signal, and the combination logic is configured to allow higher operation speed of said digital modulator system.

5. The digital modulator system as claimed in claim 1 wherein said system is configured for nested pipelining adapted to split the bus signal more than two times.

6. The digital modulator system as claimed in claim 1 wherein the combination of bus-splitting and pipelining in the modulator system is configured to provide an output signal to maximize the update rate of a multi-modulus divider of a fractional-N frequency synthesizer.

7. The digital modulator system as claimed in claim 1 wherein the first modulator is clocked at a first rate and the second modulator is clocked at a second rate.

8. A fractional-N frequency synthesizer comprising a digital modulator system, wherein the system comprises a first and a second modulator configured with a bus-splitting function and a pipelining function to allow the controller of a multi-modulus divider to operate.

9. A fractional-N frequency synthesizer comprising a digital modulator system, said system comprising:
a first pipelined modulator configured to receive a digital signal delivered via a bus signal;
a second pipelined modulator configured to receive a part of said digital signal; and
said system is adapted to split the bus signal by passing least significant bits (LSBs) of said digital signal through the second modulator, combining the output of said second modulator with the pipelined most significant bits (MSBs) of said digital signal, and adapted to pass the combined signal through said first pipelined modulator.

10. The fractional-N frequency synthesizer as claimed in claim 9 wherein said first modulator comprises a digital delta-sigma modulator.

11. The fractional-N frequency synthesizer as claimed in claim 9 wherein said second modulator comprises a digital delta-sigma modulator.

12. The fractional-N frequency synthesizer as claimed in claim 9 wherein said first modulator comprises pipelined logic, such that said pipelining of the modulators, the digital signal, and the combination logic is configured to allow higher operation speed of said digital modulator system.

13. The fractional-N frequency synthesizer as claimed in claim 9 wherein said system is configured for nested pipelining adapted to split the bus signal more than two times.

14. The fractional-N frequency synthesizer as claimed in claim 9 wherein the combination of bus-splitting and pipelining in the modulator system is configured to provide an output signal to maximize the update rate of a multi-modulus divider of a fractional-N frequency synthesizer.

15. The fractional-N frequency synthesizer as claimed in claim 9 wherein the first modulator is clocked at a first rate and the second modulator is clocked at a second rate.
